(19) United States
(12) Patent Application Publication
(10) Pub. No.: US 2005/0031998 A1
(43) Pub. Date: Feb. 10, 2005

(54) Method for manufacturing light guide plate stamper

(76) Inventors: Ga-Lane Chen, Fremont, CA (US); Kun-Jung Tsai, Tu-chen (TW); Tai-Cherng Yu, Tu-chen (TW)

Correspondence Address: WEI TE CHUNG;FOXCONN INTERNATIONAL, INC., 1650 MEMOREX DRIVE, SANTA CLARA, CA, 95050, US

(21) Appl. No.: 10/914,882

(22) Filed: Aug. 9, 2004

(30) Foreign Application Priority Data
Aug. 8, 2003 (TW) 92121866

(51) Int. Cl. G03F 7/36

(52) U.S. Cl. 430/320; 430/322; 430/323

(57) ABSTRACT

A method for manufacturing a light guide plate (LGP) stamper (26) includes the steps of: forming a photo-resist film (21) on a substrate (30); exposing and developing the photo-resist film to form micro patterns (21′); etching the substrate by means of a dry etching method to form a perform including the stamper; and stripping off residual patterns from the substrate to form the LGP stamper.

### BACKGROUND OF THE INVENTION

1. Field of the Invention

This invention generally relates to a method for manufacturing a stamper, and particularly relates to a method for manufacturing a stamper used for manufacturing a light guide plate (LGP) of a backlight module.

2. Prior Art

In recent years, implementation of word processors in compact personal computers has boomed, and portable personal computers known as laptops and notebooks are now in widespread use. In such portable personal computers, a liquid crystal display (LCD) device is commonly used as the display unit.

Conventionally, a backlight module is disposed at a rear side of an LCD screen for lighting the whole LCD screen. To achieve a display with high clarity and resolution, the backlight module providing illumination for the LCD device is required to emit light with high luminance and uniformity. The LGP of the backlight module is key to providing the needed luminance and uniformity. More particularly, the optical performance of micro patterns formed on a bottom surface of the LGP is the most important factor influencing the luminance and uniformity characteristics of the LGP.

Methods for manufacturing an LGP with micro patterns include printing techniques and non-printing techniques. A non-printing technique mainly includes the steps of transcribing predefined micro patterns to a prepared stamper; and manufacturing the LGP with the micro patterns on its bottom surface by utilizing the stamper in conjunction with an injection molding method or an extrusion molding method. Generally, non-printing techniques are considered to be superior to printing techniques, because the quality of the micro patterns manufactured by non-printing techniques is better than that of printing techniques.

Taiwan Patent No. 503,170 issued on Sep. 21, 2002, discloses a method for producing an injection molding mold for use in non-printing techniques. The method comprises: producing a patterned soft photo-mask from a soft film; using photolithography to reproduce the patterned soft photo-mask into the form of a non-conductive female mold; coating a silver film on the non-conductive female mold; electroplating the non-conductive female mold to form a mold core, in which a conductive female mold can be electroplated directly; stripping off the silver film and the non-conductive female mold from the mold core; and putting the mold core into an electrolyte solution to remove any residual silver film.

However, the above-described method for producing an injection molding mold has certain problems. In particular, a precision of the reverse micro patterns on the mold is generally not satisfactory, because these patterns are easily damaged when the silver film is stripped off or when the residual silver film is removed. In addition, said method is somewhat complicated, resulting in much manufacturing time being spent and correspondingly high costs.

### SUMMARY OF THE INVENTION

An object of the present invention is to provide a relatively easy, low-cost method for manufacturing an LGP stamper that has highly precise micro patterns formed thereon.

According to one aspect of the present invention, a method of manufacturing a stamper in accordance with the present invention comprises: forming a photo-resist film on a substrate; exposing and developing the photo-resist film to form micro patterns; and etching the substrate by means of a dry etching method to form the stamper.

Other objects, advantages, and novel features of the present invention will become more apparent from the following detailed description when taken in conjunction with the accompanying drawings.

### BRIEF DESCRIPTION OF THE DRAWINGS

FIGS. 1 to 6 are schematic, cross-sectional views of sequential steps in manufacturing a stamper in accordance with the present invention.

### DESCRIPTION OF THE PREFERRED EMBODIMENTS

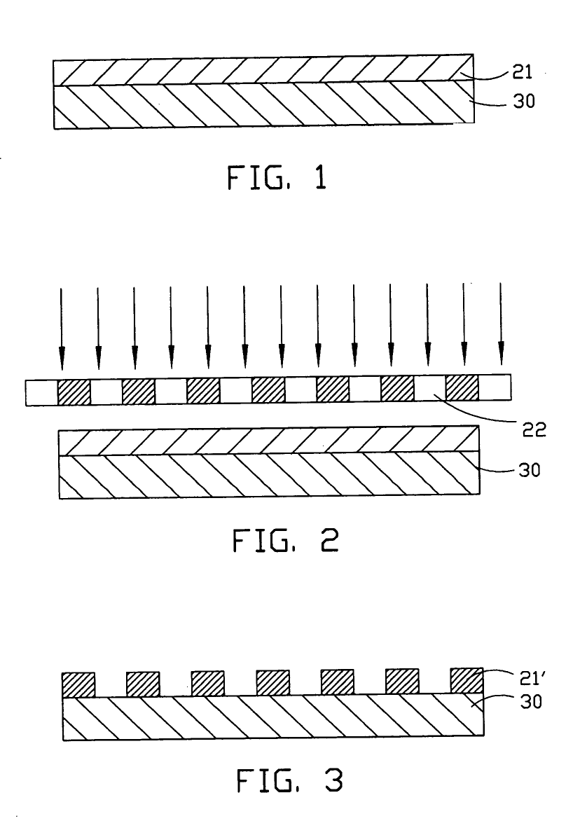

FIGS. 1 to 6 show processing steps of a preferred embodiment of a method for manufacturing an LGP stamper. Referring to these figures, said manufacturing method includes the following steps:
Preparing a metal, alloy or silicon wafer substrate 30, and forming a photo-resist film 21 on the substrate 30; exposing and developing the photo-resist film 21 utilizing a photo-mask 22 to form micro patterns 21′; etching the substrate 30 by means of a dry etching method to form a preform including a stamper 26; and stripping off or otherwise removing residual patterns 21′ from the substrate 30 to form the LGP stamper 26.

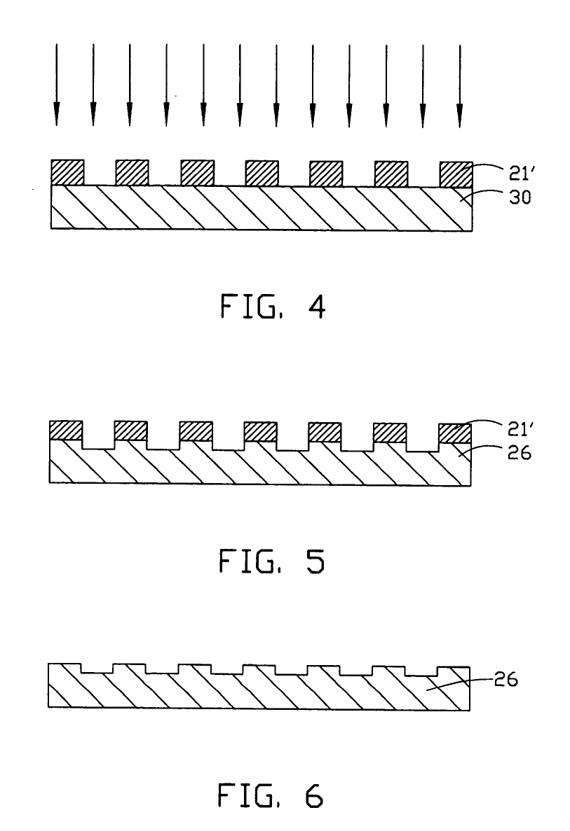

The method is described in more detail below:
(1) Preparing the metal or alloy substrate 30, and forming the photo-resist film 21 on the substrate 30, as shown in FIG. 1. First, the substrate 30 is placed in a coating machine, and the photo-resist film 21 is coated on the substrate 30 to a thickness of about 20 microns. This is performed at a speed of 4000 rpm for 25 seconds. The substrate 30 can be polished to a mirror-like quality, having a thickness of 2 to 10 millimeters. Before forming the photo-resist film 21, an adhesion promoting agent of the silane series may be applied on the substrate 30. The coating process may be a spin coating process, a roll coating process, or the like. A liquid or film-like positive or negative photo-resist material can be used for the photo-resist film 21. Second, the photo-resist film 21 is baked at 140° C. for two hours.
(2) Exposing and developing the photo-resist film 21 utilizing the photo-mask 22 to form patterns 21′, as shown in FIGS. 2 and 3. First, the patterned soft photo-mask 22 with patterns is produced. The patterns on the photo-mask 22 and the patterns of the formed LGP stamper 26 are homologous. Second, the photo-mask 22 is placed on the photo-resist film 21. The photo-mask 22 is irradiated with ultraviolet rays from above, which develops the photo-resist film 21 to thereby form corresponding patterns 21′ on the substrate 30. The exposing step may utilize electron beams, ultraviolet rays, X-rays, a laser beam, or the like.
(3) Etching the substrate 30 by means of a dry etching method to form the stamper 26, as shown in FIGS. 4 to 6. The dry etching method may be plasma etching, sputter etching, ion beam etching, or reactive ion etching. Plasma etching utilizes plasma driven by an alternating electric field to impinge on the substrate 30 and the patterns 21′ thereon. That is, the plasma carves a plurality of precise rectangular concaves in exposed surfaces of the substrate 30. Sputter etching utilizes accelerated charged particle beams to impinge on the substrate 30 and the patterns 21′ thereon. That is, the charged particle beams form concaves in exposed surfaces of the substrate 30. The direction of etching may be orthogonal or oblique to the substrate 30, resulting in profiles of the concaves being rectangular or triangular.
(4) Stripping off or otherwise removing residual patterns 21′ from the substrate 30 to form the LGP stamper 26 (see FIG. 6).

It will be understood that, unlike the above-described prior art method, the method for manufacturing the LGP stamper 26 in accordance with the present invention does not require a step of separating a silver film from the stamper 26. Thus, there is no risk of the patterns on the LGP stamper 26 sustaining serious damage. The precise micro patterns on the LGP stamper 26 remain intact. In addition, the method for manufacturing the LGP stamper 26 is simple compared to the prior art.

It is to be understood, however, that even though numerous characteristics and advantages of the present invention have been set forth in the foregoing description, together with details of the structure resulting from the invention, the disclosure is illustrative only. Changes may be made in detail, especially in matters of shape and size and of arrangement of steps, within the principles of the invention to the full extent indicated by the broad general meaning of the terms in which the appended claims are expressed.

1. A method for manufacturing a stamper, comprising:
forming a photo-resist film on a substrate;
exposing and developing the photo-resist film to form micro patterns; and
etching the substrate by means of a dry etching method to form a stamper.

2. The method for manufacturing a stamper as claimed in claim 1, wherein the substrate is etched by plasma etching.

3. The method for manufacturing a stamper as claimed in claim 1, wherein the substrate is etched by sputter etching.

4. The method for manufacturing a stamper as claimed in claim 1, wherein the substrate is etched by ion beam etching.

5. The method for manufacturing a stamper as claimed in claim 1, wherein the substrate is etched by reactive ion etching.

6. The method for manufacturing a stamper as claimed in claim 1, wherein a direction of etching is orthogonal to the substrate.

7. The method for manufacturing a stamper as claimed in claim 1, wherein a direction of etching is oblique to the substrate.

8. The method for manufacturing a stamper as claimed in claim 1, wherein the substrate is made from a metal, an alloy or a silicon wafer.

9. The method for manufacturing a stamper as claimed in claim 1, wherein the exposing step utilizes electron beams, ultraviolet rays, X-rays or a laser beam.

10. The method for manufacturing a stamper as claimed in claim 1, further comprising the step of coating an adhesion promoting agent of the silane series on the substrate.

11. A method for making a light guide plate, comprising steps of:
forming a photo-resist film on a substrate;
exposing and developing the photo-resist film to form micro patterns;
etching the substrate by means of a dry etching method to form a stamper; and
making the light guide plate via injection molding with the stamper.

12. A method for making a light guide plate, comprising steps of:
forming a photo-resist film on a substrate;
exposing and developing the photo-resist film to form micro patterns;
etching the substrate by means of an etching method to form a stamper; wherein
said etching method essentially combines physical blasting and chemical reaction effects together.
